(19) United States
(12) Patent Application Publication
(10) Pub. No.: US 2023/0337445 A1
(43) Pub. Date: Oct. 19, 2023

(54) PHOTOELECTRIC CONVERSION ELEMENT AND IMAGING DEVICE

(71) Applicant: SONY SEMICONDUCTOR SOLUTIONS CORPORATION, KANAGAWA (JP)

(72) Inventor: OSAMU ENOKI, KANAGAWA (JP)

(21) Appl. No.: 18/044,580

(22) PCT Filed: Aug. 19, 2021
(86) PCT No.: PCT/JP2021/030405

§ 371 Date: Mar. 9, 2023

(30) Foreign Application Priority Data
Sep. 17, 2020 (JP) 2020-156660

(51) Int. Cl. H10K 39/32; H10K 30/85; H10K 39/38; H10K 30/20; H10K 30/86; H10K 30/30; H10K 85/60

(52) U.S. Cl. CPC H10K 39/32; H10K 30/85; H10K 39/38; H10K 30/20; H10K 30/86; H10K 30/353; H10K 85/6572; H10K 2101/30

(57) ABSTRACT

A photoelectric conversion element according to an embodiment of the present disclosure includes: a first electrode; a second electrode disposed to be opposed to the first electrode; an organic photoelectric conversion layer provided between the first electrode and second electrode; and a buffer layer provided between the first electrode and the organic photoelectric conversion layer, and including a mellitic acid derivative represented by the general formula (1).

### TECHNICAL FIELD

The present disclosure relates to a photoelectric conversion element using, for example, an organic material and an imaging device including the photoelectric conversion element.

### BACKGROUND ART

For example, PTL 1 discloses a photoelectric conversion element including a first electrode, an organic photoelectric conversion layer, and a second electrode stacked in this order, in which a charge injection blocking layer including a material with a naphthalene diimide structure, for example, and an underlayer including a material with a pyridine terminal, for example, are stacked in this order between the first electrode and the organic photoelectric conversion layer, from a side of the first electrode, for example.

### CITATION LIST

### Patent Literature

PTL 1: Japanese Unexamined Patent Application Publication No. 2018-98438

### SUMMARY OF THE INVENTION

Incidentally, it is required, for a photoelectric conversion element used as an imaging element, to have an improvement in heat resistance.

It is desirable to provide a photoelectric conversion element and an imaging device that make it possible to improve heat resistance.

A photoelectric conversion element according to an embodiment of the present disclosure includes: a first electrode; a second electrode disposed to be opposed to the first electrode; an organic photoelectric conversion layer provided between the first electrode and second electrode; and a buffer layer provided between the first electrode and the organic photoelectric conversion layer, and including a mellitic acid derivative represented by the following general formula (1).

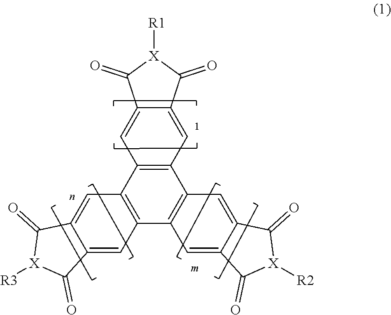

(X is each independently an oxygen atom, a nitrogen atom, or a sulfur atom. R1 to R3 are each independently a hydrogen atom, a halogen atom, an aromatic hydrocarbon group having 6 to 60 carbon atoms, an aromatic heterocyclic group having 3 to 30 carbon atoms, a haloalkyl group having 1 to 30 carbon atoms, an alkylamino group having 1 to 30 carbon atoms, a dialkylamino group having 2 to 60 carbon atoms, an alkylsulfonyl group having 1 to 30 carbon atoms, a haloalkylsulfonyl group having 1 to 3 carbon atoms, an alkylsilyl group having 3 to 30 carbon atoms, an alkylsilylacetylene group having 5 to 60 carbon atoms, a cyano group, or a derivative thereof. l, m, and n are an integer of 0 or 1 or more and 5 or less.)

An imaging device according to an embodiment of the present disclosure includes one or multiple photoelectric conversion elements according to an embodiment of the present disclosure for each of multiple pixels.

In the photoelectric conversion element and the imaging device of an embodiment of the present disclosure, providing a buffer layer including a mellitic acid derivative represented by the above general formula (1) that is less likely to crystallize than naphthalene diimides, for example, between the first electrode and the organic photoelectric conversion layer, which is provided between the first electrode and the second electrode disposed to be opposed to each other, allows for an improvement in heat resistance of the buffer layer.

### BRIEF DESCRIPTION OF THE DRAWINGS

FIG. 1 is a schematic cross-sectional view of an example of a configuration of a photoelectric conversion element according to an embodiment of the present disclosure.

FIG. 2 is a block diagram illustrating an overall configuration of an imaging element including the photoelectric conversion element illustrated in FIG. 1.

FIG. 3 is a schematic cross-sectional view of an example of an outline configuration of the imaging element illustrated in FIG. 2.

FIG. 4 is an equivalent circuit diagram of an organic photoelectric conversion section illustrated in FIG. 3.

FIG. 5 is an equivalent circuit diagram of an inorganic photoelectric conversion section illustrated in FIG. 3.

FIG. 6A is a schematic cross-sectional view of an example of a configuration of an imaging element according to Modification Example 1 of the present disclosure.

FIG. 6B is a schematic planar view of an example of a pixel configuration of the imaging element illustrated in FIG. 6A.

FIG. 7A is a schematic cross-sectional view of an example of a configuration of an imaging element according to Modification Example 2 of the present disclosure.

FIG. 7B is a schematic planar view of an example of a pixel configuration of the imaging element illustrated in FIG. 7A.

FIG. 8 is a schematic cross-sectional view of an example of an outline configuration of an imaging element according to Modification Example 3 of the present disclosure.

FIG. 9 is a block diagram illustrating a configuration example of an electronic apparatus including the imaging element illustrated in FIG. 2, etc.

FIG. 10 is a view depicting an example of a schematic configuration of an endoscopic surgery system.

FIG. 11 is a block diagram depicting an example of a functional configuration of a camera head and a camera control unit (CCU).

FIG. 12 is a block diagram depicting an example of schematic configuration of a vehicle control system.

FIG. 13 is a diagram of assistance in explaining an example of installation positions of an outside-vehicle information detecting section and an imaging section.

### MODES FOR CARRYING OUT THE INVENTION

In the following, description is given in detail of embodiments of the present disclosure with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.
1. Embodiment (An example of a photoelectric conversion element provided with a buffer layer including a mellitic acid derivative between a lower electrode and an organic photoelectric conversion layer)
   1-1. Configuration of Photoelectric Conversion Element
   1-2. Configuration of Imaging Element
   1-3. Workings and Effects
2. Modification Examples
   2-1. Modification Example 1 (An example of an imaging element including a lower electrode including multiple electrodes)
   2-2. Modification Example 2 (An example of a photoelectric conversion element that performs spectroscopy of an inorganic photoelectric conversion section using a color filter)
   2-3. Modification Example 3 (An example of a vertical spectroscopic imaging element in which one organic photoelectric conversion section and two inorganic photoelectric conversion sections are stacked in a vertical direction)
3. Application Example
4. Practical Application Examples

### 1. EMBODIMENT

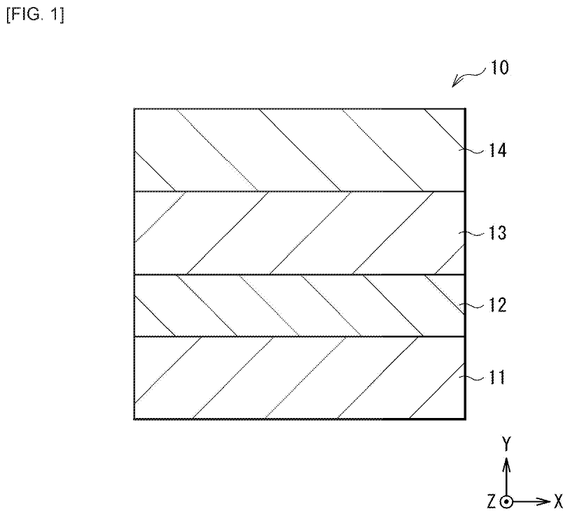

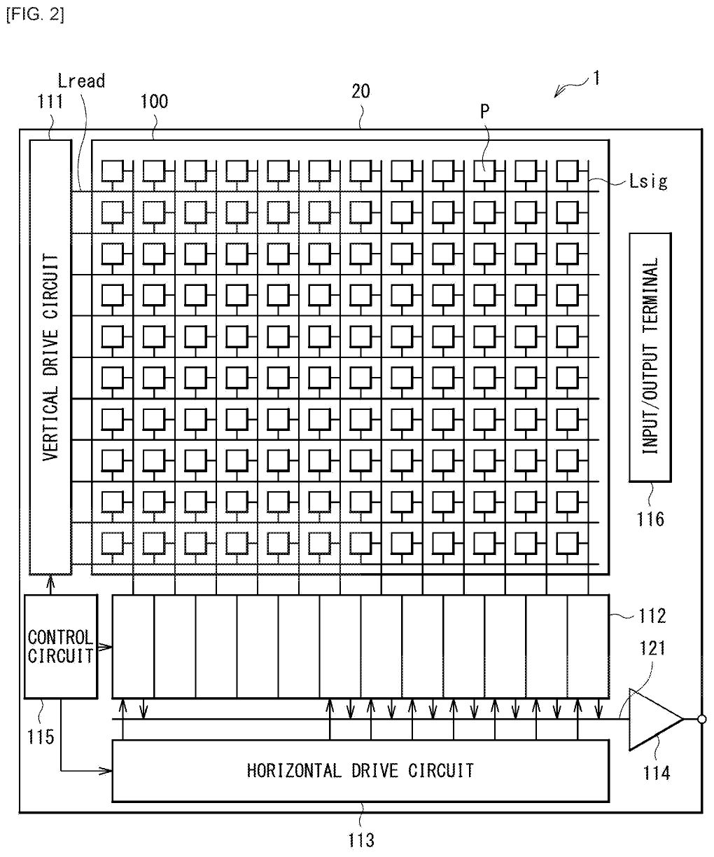

FIG. 1 schematically illustrates an example of a cross-sectional configuration of an organic photoelectric conversion section (an organic photoelectric conversion section 10) corresponding to a photoelectric conversion element according to an embodiment of the present disclosure. The organic photoelectric conversion section 10 is used for each pixel (a unit pixel P) in an imaging element (an imaging element 1, see FIG. 2) such as a CMOS (Complementary Metal Oxide Semiconductor) image sensor to be used, for example, in an electronic apparatus such as a digital still camera or a video camera. In the organic photoelectric conversion section 10 of the present embodiment, a lower electrode 11, a buffer layer 12, an organic photoelectric conversion layer 13, and an upper electrode 14 are stacked in this order. The buffer layer 12 includes a mellitic acid derivative represented by the general formula (1) described later.

### 1-1. Configuration of Photoelectric Conversion Element

The organic photoelectric conversion section 10 absorbs light corresponding to a portion or all of wavelengths of a visible light region (e.g., a wavelength of 400 nm or more and less than 700 nm), for example, to generate electron-hole pairs (excitons). In the organic photoelectric conversion section 10, for example, electrons, of the electron-hole pairs generated by photoelectric conversion, are read as signal charges from a side of the lower electrode 11, in the imaging element 1 described later. In the following, description is given of configurations, materials, and the like of respective components, by exemplifying the case of reading electrons as signal charges.

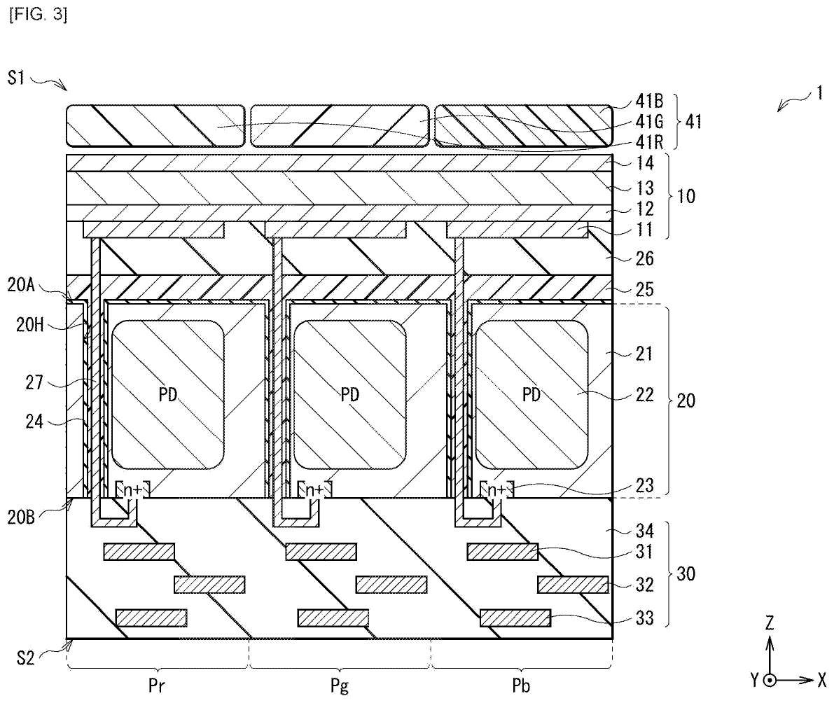

The lower electrode 11 is provided to attract signal charges, of electric charges generated in the organic photoelectric conversion layer 13, and to transfer the attracted signal charges to a charge-holding section 23 (see FIG. 3). The lower electrode 11 is formed by a light transmissive electrically-conductive film. Examples of a material of the lower electrode 11 include indium tin oxide (ITO), In₂O₃ doped with tin (Sn) as a dopant, indium tin oxides including crystalline ITO and amorphous ITO. As a material of the lower electrode 11, a tin oxide (SnO₂)-based material doped with a dopant or a zinc oxide-based material doped with a dopant may be used, in addition to those described above. Examples of the zinc oxide-based material include aluminum zinc oxide (AZO) doped with aluminum (Al) as a dopant, gallium zinc oxide (GZO) doped with gallium (Ga), boron zinc oxide doped with boron (B), and indium zinc oxide (IZO) doped with indium (In). In addition, Cul, InSbO₄, ZnMgO, CuInO₂, MgIN₂O₄, CdO, ZnSnO₃, TiO₂, or the like may be used as a material of the lower electrode 11. Further, a spinel-type oxide or an oxide having a YbFe₂O₄ structure may be used.

The buffer layer 12 functions as a so-called electron transport/hole blocking layer that selectively transfers electrons, of the electric charges generated in the organic photoelectric conversion layer 13, to the lower electrode 11 and inhibits movement of holes to the side of the lower electrode 11. The buffer layer 12 can be formed using an electron-transporting material, and preferably has a Lowest Unoccupied Molecular Orbital (LUMO) level equivalent to or deeper than electron affinity of the organic photoelectric conversion layer 13 described later, for example. It is to be noted that, as used herein, the term “equivalent” means, for example, a range of ±0.2 eV with respect to the electron affinity of the organic photoelectric conversion layer 13. Examples of a material satisfying the above-described energy level include a mellitic acid derivative represented by the following general formula (1).

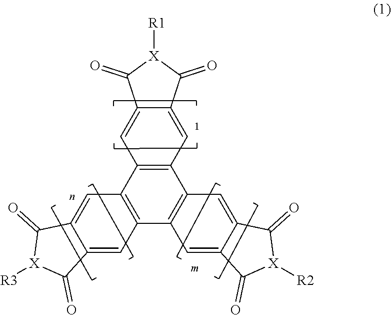

(X is each independently an oxygen atom, a nitrogen atom, or a sulfur atom. R1 to R3 are each independently a hydrogen atom, a halogen atom, an aromatic hydrocarbon group having 6 to 60 carbon atoms, an aromatic heterocyclic group having 3 to 30 carbon atoms, a haloalkyl group having 1 to 30 carbon atoms, an alkylamino group having 1 to 30 carbon atoms, a dialkylamino group having 2 to 60 carbon atoms, an alkylsulfonyl group having 1 to 30 carbon atoms, a haloalkylsulfonyl group having 1 to 3 carbon atoms, an alkylsilyl group having 3 to 30 carbon atoms, an alkylsilylacetylene group having 5 to 60 carbon atoms, a cyano group, or a derivative thereof. l, m, and n are an integer of 0 or 1 or more and 5 or less.)

Of the mellitic acid derivative represented by the above general formula (1), it is particularly preferable to use mellitic trianhydride represented by the following general formula (2), mellitic triimide represented by the general formula (3), and derivatives thereof.

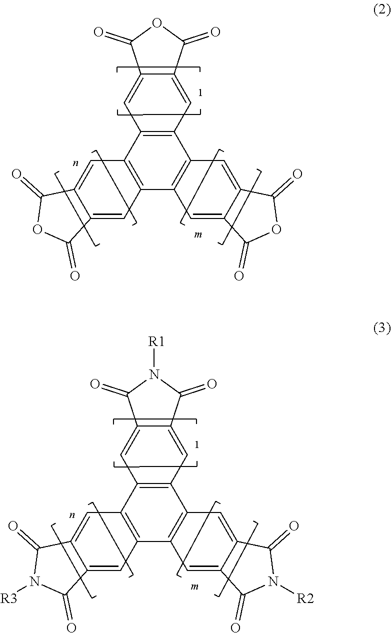

Examples of the mellitic trianhydride represented by the above general formula (2), the mellitic triimide represented by the general formula (3), and derivatives thereof include compounds represented by the following formulae (1-1) to (1-26).

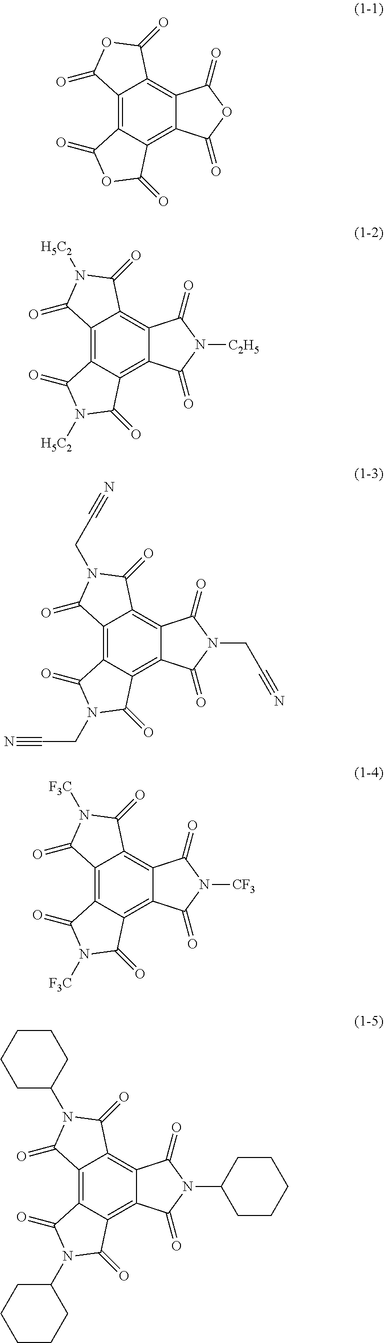

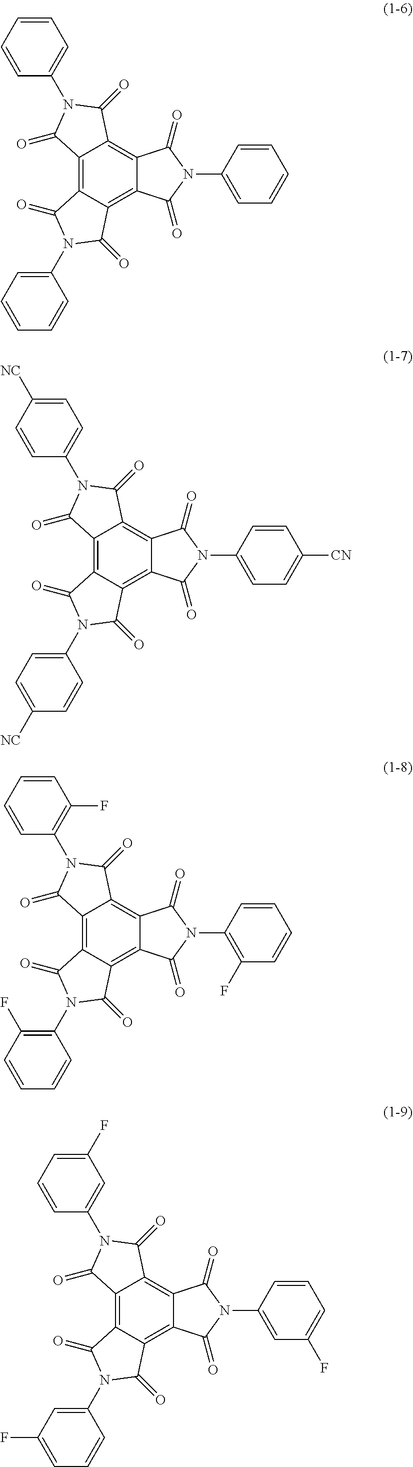

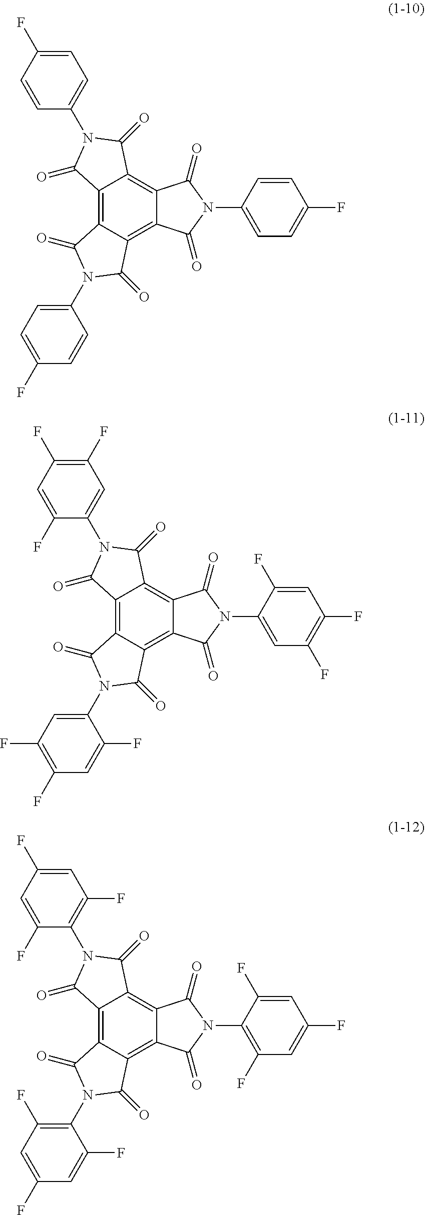

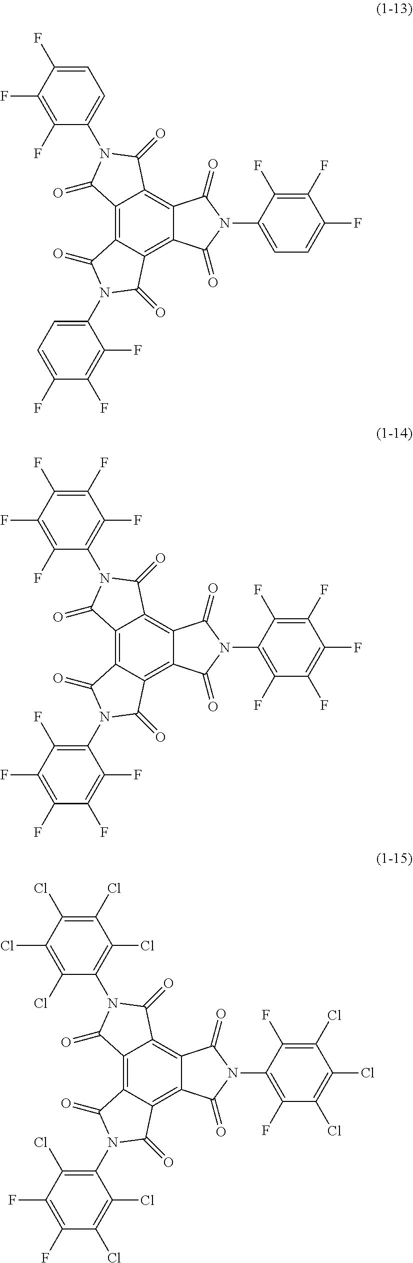

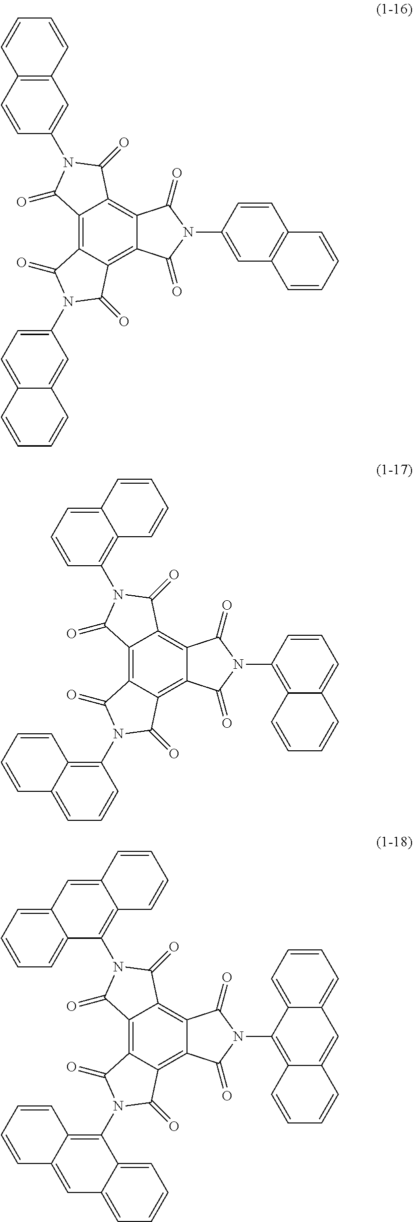

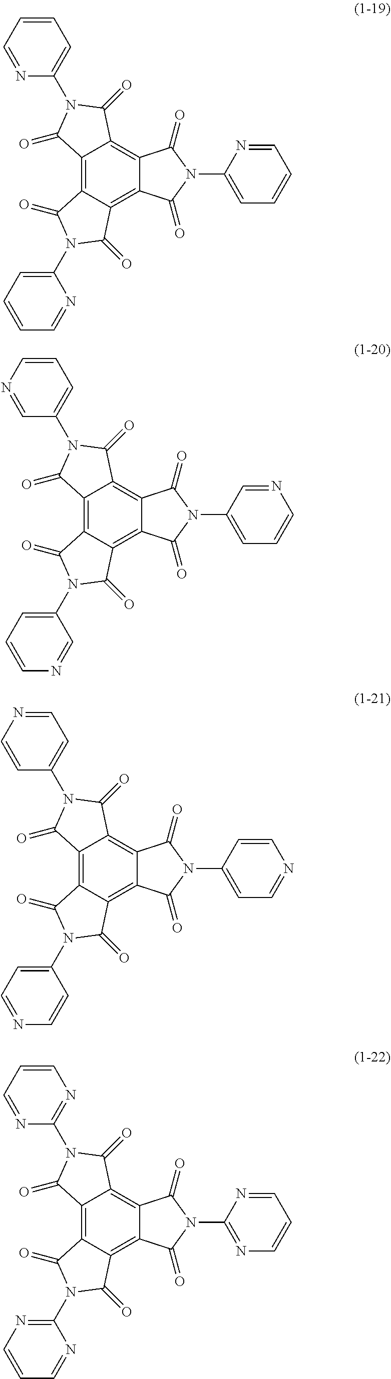

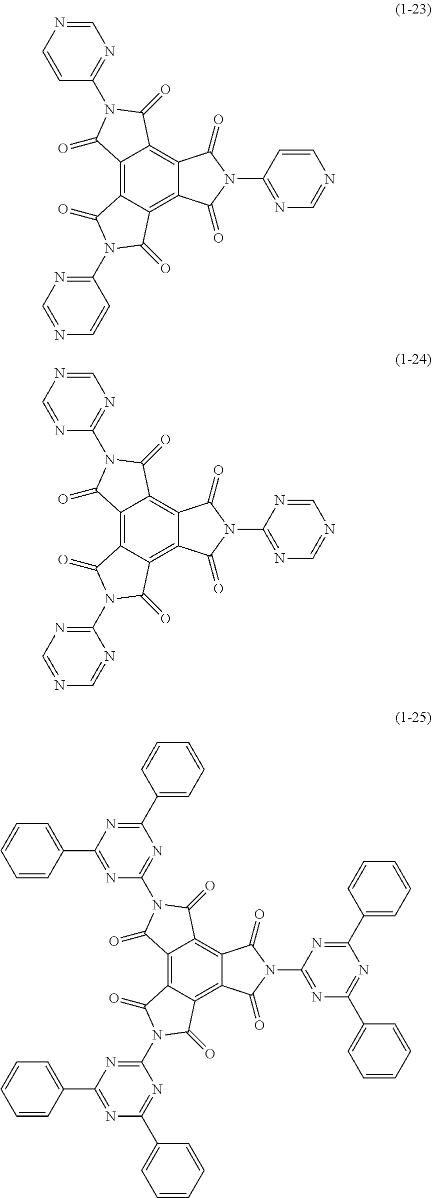

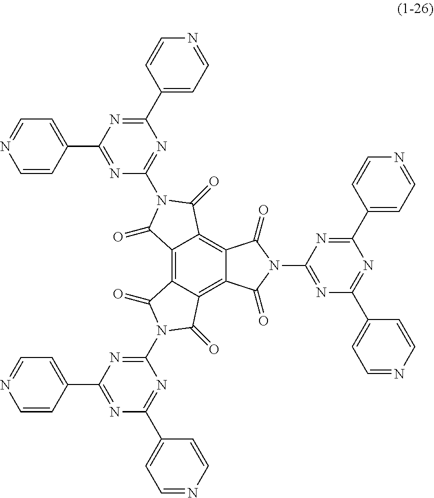

In addition, the above formulae (1-1) to (1-26) exemplify compounds of which values of l, m, and n are equal to one another; however, this is not limitative. The values of l, m, and n may be different from one another; it may be possible to use, as a material of the buffer layer 12, for example, a compound represented by the following formula (1-27) in which l=0, m=1, and n=2 hold true. Further, it may be possible to use, as the material of the buffer layer 12, for example, an oligomer in which multiple mellitic derivatives are linked via any of R1, R2, and R3 of mellitic triimide represented by the general formula (3), as exemplified in the following formula (1-28).

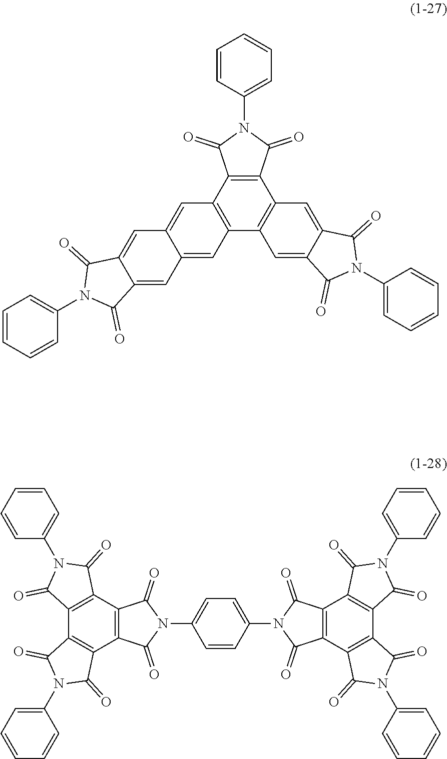

The LUMO level preferably has a value deeper than 4.0 eV as in the compound represented by the formula (1-21) in which R1 to R3 are a 4-pyridyl group, for example, as the material of the buffer layer 12, among the mellitic acid derivatives mentioned above.

The buffer layer 12 may be a layer only of the above-described mellitic acid derivative, or may be a mixed layer including a material other than the mellitic acid derivative. In addition, the buffer layer 12 may have a monolayer structure, or may have a stacked structure of a layer of a mellitic acid derivative and a layer of another material.

The organic photoelectric conversion layer 13 converts optical energy into electric energy, and includes two or more organic materials that function as a p-type semiconductor and an n-type semiconductor, for example. The p-type semiconductor relatively functions as an electron donor, and the n-type semiconductor relatively functions as an electron acceptor. The organic photoelectric conversion layer 13 includes, in the layer, a bulk-hetero junction structure. The bulk-hetero junction structure is a p/n junction surface formed by mixing of the p-type semiconductor and the n-type semiconductor; excitons generated upon light absorption separate into electrons and holes at this p/n junction interface.

The organic photoelectric conversion layer 13 may further include a so-called dye material that photoelectrically convert light of a predetermined wavelength band while transmitting light of another wavelength band, in addition to the p-type semiconductor and the n-type semiconductor. The p-type semiconductor, the n-type semiconductor, and the dye material preferably have different absorption local maximum wavelengths. This makes it possible to absorb a wavelength of a visible light region at a wide range.

Examples of a specific material of the organic photoelectric conversion layer 13 include the following organic materials. Examples of the n-type semiconductor include fullerenes having an electron-transporting property such as C₆₀ fullerene and C₇₀ fullerene or derivatives thereof. Examples of the p-type semiconductor include polyacenes having a hole-transporting property such as pentacene, thienoacenes having a hole-transporting property represented by benzothienobenzothiophene (BTBT) and dinaphthothienothiophene (DNTT), and derivatives thereof.

The buffer layer 12 and the organic photoelectric conversion layer 13 described above can be formed, for example, using a vacuum deposition method, for example. Alternatively, the buffer layer 12 and the organic photoelectric conversion layer 13 can be formed, for example, using a spin coating technique, a printing technique, or the like.

The upper electrode 14 can be formed by a light-transmissive electrically-conductive film, similarly to the lower electrode 11.

It is to be noted that another layer may be further provided between the organic photoelectric conversion layer 13 and the lower electrode 11 and between the organic photoelectric conversion layer 13 and the upper electrode 14. For example, there may be provided, between the organic photoelectric conversion layer 13 and the upper electrode 14, a layer that functions as a so-called hole transport/electron blocking layer that selectively transfers holes, of the electric charges generated in the organic photoelectric conversion layer 13, to the upper electrode 14 and inhibits movement of electrons to a side of the upper electrode 14.

### 1-2. Configuration of Imaging Element

FIG. 2 illustrates an example of an overall configuration of the imaging element (imaging element 1) according to an embodiment of the present disclosure. As described above, the imaging element 1 is, for example, a CMOS image sensor. The imaging element 1 takes in incident light (image light) from a subject via an optical lens system (unillustrated), and converts the amount of incident light formed as an image on an imaging surface into electric signals in units of pixels to output the electric signals as pixel signals. The imaging element 1 includes a pixel section 100 as an imaging area on a semiconductor substrate 20. In addition, the imaging element 1 includes, for example, a vertical drive circuit 111, a column signal processing circuit 112, a horizontal drive circuit 113, an output circuit 114, a control circuit 115, and an input/output terminal 116 in a peripheral region of this pixel section 100.

The pixel section 100 includes, for example, the multiple unit pixels P that are two-dimensionally arranged in matrix. The unit pixels P are provided, for example, with a pixel drive line Lread (specifically, a row selection line and a reset control line) for each of pixel rows and provided with a vertical signal line Lsig for each of pixel columns. The pixel drive line Lread transmits drive signals for reading signals from the pixels. One end of the pixel drive line Lread is coupled to an output terminal of the vertical drive circuit 111 corresponding to each of the rows.

The vertical drive circuit 111 is a pixel drive section that is configured by a shift register, an address decoder, and the like and drives the unit pixels P of the pixel section 100 on a row-by-row basis, for example. Signals outputted from the respective unit pixels P in the pixel rows selectively scanned by the vertical drive circuit 111 are supplied to the column signal processing circuit 112 through the respective vertical signal lines Lsig. The column signal processing circuit 112 is configured by an amplifier, a horizontal selection switch, and the like provided for each of the vertical signal lines Lsig.

The horizontal drive circuit 113 is configured by a shift register, an address decoder, and the like. The horizontal drive circuit 113 drives horizontal selection switches of the column signal processing circuit 112 in order while scanning the horizontal selection switches. The selective scanning by the horizontal drive circuit 113 causes signals of the respective pixels transmitted through the respective vertical signal lines Lsig to be outputted to a horizontal signal line 121 in order and causes the signals to be transmitted to the outside of the semiconductor substrate 20 through the horizontal signal line 121.

The output circuit 114 performs signal processing on signals sequentially supplied from the respective column signal processing circuits 112 via the horizontal signal line 121, and outputs the signals. The output circuit 114 performs, for example, only buffering in some cases, and performs black level adjustment, column variation correction, various kinds of digital signal processing, and the like in other cases.

The circuit portion including the vertical drive circuit 111, the column signal processing circuit 112, the horizontal drive circuit 113, the horizontal signal line 121, and the output circuit 114 may be formed directly on the semiconductor substrate 20, or may be provided on an external control IC. In addition, the circuit portion may be formed in another substrate coupled by a cable or the like.

The control circuit 115 receives a clock supplied from the outside of the semiconductor substrate 20, data for an instruction about an operation mode, and the like, and also outputs data such as internal information on the imaging element 1. The control circuit 115 further includes a timing generator that generates a variety of timing signals, and controls driving of the peripheral circuits including the vertical drive circuit 111, the column signal processing circuit 112, the horizontal drive circuit 113, and the like on the basis of the variety of timing signals generated by the timing generator.

The input/output terminal 116 exchanges signals with the outside.

FIG. 3 schematically illustrates an example of a cross-sectional configuration of each unit pixel P illustrated in FIG. 2.

The imaging element 1 is a so-called vertical spectroscopic imaging element in which the above-described one organic photoelectric conversion section 10 and one inorganic photoelectric conversion section 22 are stacked in a vertical direction (e.g., Z-axis direction) in each of the multiple unit pixels P two-dimensionally arranged in matrix of the pixel section 100.

The inorganic photoelectric conversion section 22 is configured by, for example, a photodiode PD embedded inside the semiconductor substrate 20 having a first surface 20A (back surface) and a second surface 20B (front surface) opposed to each other. It is to be noted that, in FIG. 3, the back surface (first surface 20A) side of the semiconductor substrate 20 is denoted by a light incident side S1, and the front surface (second surface 20B) side is denoted by a wiring layer side S2.

The organic photoelectric conversion section 10 is provided on the light incident side S1 with respect to the inorganic photoelectric conversion section 22, in particular, on the first surface 20A side of the semiconductor substrate 20. The organic photoelectric conversion section 10 and the inorganic photoelectric conversion section 22 detect light beams of different wavelength bands to perform photoelectric conversion. Specifically, the organic photoelectric conversion section 10 detects a portion or all of wavelengths of a visible light region (e.g., a wavelength of 400 nm or more and less than 700 nm) as described above, whereas the inorganic photoelectric conversion section 22 detects a portion or all of wavelengths of an infrared region (e.g., a wavelength of 700 nm or more and 1000 nm or less).

The second surface 20B of the semiconductor substrate 20 is provided with, for example, the charge-holding section 23, a readout circuit having, for example, a transfer transistor (TG), an amplification transistor (AMP), a reset transistor (RST), a selection transistor (SEL) and the like, and a multilayer wiring layer 30. In the multilayer wiring layer 30, for example, wiring layers 31, 32, and 33 are stacked inside an insulating layer 34.

A fixed charge layer 24, an antireflection layer 25, and an interlayer insulating layer 26 are stacked in this order on the first surface 20A of the semiconductor substrate 20. The fixed charge layer 24 further extends on a side surface of a through-hole 20H that penetrates between the first surface 20A and the second surface 20B of the semiconductor substrate 20. The antireflection layer 25 is further formed to be embedded between the fixed charge layer 24 and a through-electrode 27 described later inside the through-hole 20H.

There is provided the through-electrode 27 in the through-hole 20H that penetrates between the first surface 20A and the second surface 20B of the semiconductor substrate 20. The through-electrode 27 has a function as a connector between the organic photoelectric conversion section 10 and the charge-holding section 23. The through-electrode 27 serves as a transmission path of the signal charges generated by the organic photoelectric conversion section 10. The organic photoelectric conversion section 10 is provided on the first surface 20A side of the semiconductor substrate 20. The charge-holding section 23 is provided on the second surface 20B of the semiconductor substrate 20. This allows the each of the unit pixels P to favorably transfer the signal charges generated by the organic photoelectric conversion section 10 on the first surface 20A side of the semiconductor substrate 20 to the second surface 20B side of the semiconductor substrate 20 via the through-electrode 27 and thus to enhance the characteristics. The fixed charge layer 24 and the antireflection layer 25 are provided around the through-electrode 27. This electrically insulates the through-electrode 27 and a p-well 21 from each other.

There are provided color filters 41 (color filters 41R, 41G, and 41B) above the organic photoelectric conversion section 10 (light incident side S1) for the respective unit pixels P (unit pixels Pr, Pg, and Pb). The color filters 41 (color filters 41R, 41G, and 41B) selectively transmit red light (R), green light (G), and blue light (B). This causes the organic photoelectric conversion section 10 to detect the red light transmitted through the color filter 41R in the unit pixel Pr provided with the color filter 41R and generate the signal charges corresponding to the red light (R). The organic photoelectric conversion section 10 detects the green light transmitted through the color filter 41G in the unit pixel Pg provided with the color filter 41G, and generates the signal charges corresponding to the green light (G). The organic photoelectric conversion section 10 detects the blue light transmitted through the color filter 41B in the unit pixel Pb provided with the color filter 41B, and generates the signal charges corresponding to the blue light (B).

Although not illustrated, there are further provided, for example, optical members such as a planarization layer and an on-chip lens above the color filter 41.

A band-pass filter including, for example, a dielectric multilayer film may be provided between the organic photoelectric conversion section 10 and the inorganic photoelectric conversion section 22, specifically, between the organic photoelectric conversion section 10 and the interlayer insulating layer 26. The band-pass filter has a transmission band in the infrared region, and reflects visible light while absorbing a portion of the visible light. This causes the inorganic photoelectric conversion sections 22 of the respective unit pixels Pr, Pg, and Pb to detect light beams having infrared components with aligned spectra, and generate the signal charges corresponding to the infrared ray.

It is to be noted that it is desirable to keep the distance as short as possible between the organic photoelectric conversion section 10 and the inorganic photoelectric conversion section 22 in the imaging element 1 from the viewpoint of oblique incidence characteristics.

In the imaging element 1, light beams (red light (R), green light (G), and blue light (B)) in a visible light region, of the light transmitted through the color filter 41, are absorbed by the organic photoelectric conversion section 10 of the unit pixels (Pr, Pg, and Pb), respectively, provided with the respective color filters, whereas other light beams, e.g., an infrared ray (IR) is transmitted through the organic photoelectric conversion section 10. The infrared ray (IR) transmitted through the organic photoelectric conversion section 10 is detected by the inorganic photoelectric conversion section 22 of each of the unit pixels Pr, Pg, and Pb, and signal charges corresponding to the infrared ray (IR) are generated in each of the unit pixels Pr, Pg, and Pb. That is, it is possible for the imaging element 1 to generate both of a visible light image and an infrared image simultaneously.

Description is given below in detail of configurations and materials of respective sections constituting the unit pixel P.

The organic photoelectric conversion section 10 detects a portion or all of wavelengths in the visible light region. The organic photoelectric conversion section 10 has a configuration in which the lower electrode 11, the buffer layer 12, the organic photoelectric conversion layer 13, and the upper electrode 14, which are described above, are stacked in this order. The electric charges (electrons and holes) generated in the organic photoelectric conversion layer 13 are transported to different electrodes by diffusion due to a carrier concentration difference and by an internal electric field caused by a work function difference between the anode and the cathode. The transported electric charges are detected as a photocurrent. In addition, the application of a potential between the lower electrode 11 and the upper electrode 14 makes it possible to control the transport directions of electrons and holes. In the present embodiment, as described above, electrons are read as signal charges from the side of the lower electrode 11.

The semiconductor substrate 20 is configured by, for example, an n-type silicon (Si) substrate, and includes the p-well 21 in a predetermined region.

The inorganic photoelectric conversion section 22 is configured by, for example, a PIN (Positive Intrinsic Negative) type photodiode PD, and has a p-n junction in a predetermined region of the semiconductor substrate 20.

The charge-holding section 23 includes a region (n+ region) that is provided in the semiconductor substrate 20 and has a high n-type impurity concentration.

The fixed charge layer 24 may be a film having positive fixed electric charges or a film having negative fixed electric charges. It is preferable that the fixed charge layer 24 be formed by using a semiconductor material or an electrically conductive material having a wider band gap than that of the semiconductor substrate 20. This makes it possible to suppress the generation of a dark current at an interface of the semiconductor substrate 20. Examples of a material of the fixed charge layer 24 include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), aluminum oxynitride (AlOₓN_{y}), and the like.

The antireflection layer 25 is provided to prevent the reflection of light caused by a refractive index difference between the semiconductor substrate 20 and the interlayer insulating layer 26. It is preferable that a material of the antireflection layer 25 be a material having a refractive index between the refractive index of the semiconductor substrate 20 and the refractive index of the interlayer insulating layer 26. Examples of a material of the antireflection layer 25 include tantalum oxide (TaOₓ), silicon oxide (SiOₓ), TEOS, silicon nitride (SiNₓ), silicon oxynitride (SiON), and the like.

The interlayer insulating layer 26 includes, for example, a monolayer film of one of silicon oxide (SiOₓ), TEOS, silicon nitride (SiNₓ), silicon oxynitride (SiON), or the like, or a stacked film of two or more thereof.

It is possible to form the through-electrode 27 by using, for example, a metal material such as aluminum (Al), tungsten (W), titanium (Ti), cobalt (Co), hafnium (Hf), and tantalum (Ta), in addition to a doped silicon material such as PDAS (Phosphorus Doped Amorphous Silicon).

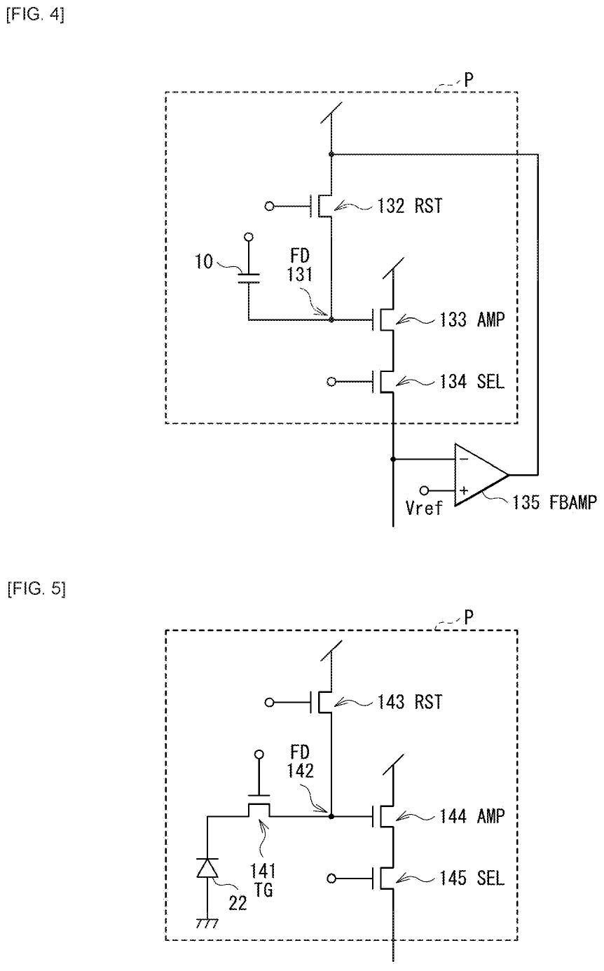

FIGS. 4 and 5 illustrate examples of readout circuits of the organic photoelectric conversion section 10 (FIG. 4) and the inorganic photoelectric conversion section 22 (FIG. 5) constituting the unit pixel P of the imaging element 1 illustrated in FIGS. 2 and 3.

### Readout Circuit of Organic Photoelectric Conversion Section

The readout circuit of the organic photoelectric conversion section 10 includes, for example, a floating diffusion (FD) 131, a reset transistor RST 132, an amplification transistor AMP 133, and a selection transistor SEL 134. Further, the unit pixel P is provided with a feedback amplifier FBAMP 135 for feeding back a readout signal to a reset signal for the readout circuit.

The FD 131 is coupled between the organic photoelectric conversion section 10 and the amplification transistor AMP 133. The FD 131 performs electric charge voltage conversion to convert the signal charges generated by the organic photoelectric conversion section 10 into a voltage signal, and outputs the converted voltage signal to the amplification transistor AMP 133.

The amplification transistor AMP 133, in which a gate electrode thereof is coupled to the FD 131 and a drain electrode is coupled to the power source section, serves as an input part of a readout circuit of the voltage signal held by the FD 131, or a so-called source follower circuit. That is, a source electrode of the amplification transistor AMP 133 is coupled to the vertical signal line Lsig via the selection transistor SEL 134 to thereby configure the source follower circuit with a constant current source coupled to one end of the vertical signal line Lsig.

The selection transistor SEL 134 is coupled between the source electrode of the amplification transistor AMP 133 and the vertical signal line Lsig. A drive signal SELsig is applied to a gate electrode of the selection transistor SEL 134. When the drive signal SELsig is brought into an active state, the selection transistor SEL 134 is brought into an electrically-conductive state, and the unit pixel P is brought into a selected state. This allows a readout signal (pixel signal) outputted from the amplification transistor AMP 133 to be outputted to the pixel drive line Lread via the selection transistor SEL 134.

The reset transistor RST 132 is coupled between the FD 131 and the power source section. A drive signal RSTsig is applied to a gate electrode of the reset transistor RST 132. In a case where this drive signal RSTsig is brought into an active state, a reset gate of the reset transistor RST 132 is brought into an electrically-conductive state, and the FD 131 is supplied with a reset signal to reset the FD 131.

The feedback amplifier FBAMP 135 has one (−) of the input terminals coupled to the vertical signal line Lsig coupled to the selection transistor SEL 134 and has the other input terminal (+) coupled to a reference voltage section (Vref). An output terminal of the feedback amplifier FBAMP 135 is coupled between the reset transistor RST 132 and the power source section. The feedback amplifier FBAMP 135 feeds back a readout signal (pixel signal) from each of the unit pixels P to a reset signal by the reset transistor RST 132.

Specifically, when the reset transistor RST 132 resets the FD 131, the drive signal RSTsig is brought into an active state, and the reset gate is brought into an electrically-conductive state. At this time, the feedback amplifier FBAMP 135 provides a necessary gain to an output signal of the selection transistor SEL 134 for feedback to cancel noise of the input part of the amplification transistor AMP 133.

### Readout Circuit of Inorganic Photoelectric Conversion Section

The readout circuit of the inorganic photoelectric conversion section 22 includes, for example, a transfer transistor TG 141, FD 142, a reset transistor RST 143, an amplification transistor AMP 144, and a selection transistor SEL 145.

The transfer transistor TG 141 is coupled between the inorganic photoelectric conversion section 22 and the FD 142. A drive signal TGsig is applied to a gate electrode of the transfer transistor TG 141. When the drive signal TGsig is brought into an active state, the transfer gate of the transfer transistor TG 141 is brought into an electrically-conductive state, and the signal charges accumulated in the inorganic photoelectric conversion section 22 are transferred to the FD 142 via the transfer transistor TG 141.

The FD 142 is coupled between the transfer transistor TG 141 and the amplification transistor AMP 144. The FD 142 performs electric charges voltage conversion to convert the signal charges transferred by the transfer transistor TG 141 into a voltage signal, and outputs the converted voltage signal to the amplification transistor AMP 144.

A reset transistor RST 133 is coupled between the FD 142 and the power source section. The drive signal RSTsig is applied to a gate electrode of the reset transistor RST 133. When the drive signal RSTsig is brought into an active state, the reset gate of the reset transistor RST 133 is brought into an electrically-conductive state, and the potential of the FD 142 is reset to the level of the power source section.

The amplification transistor AMP 144, in which a gate electrode thereof is coupled to the FD 142 and a drain electrode is coupled to the power source section, serves as an input part of a readout circuit of the voltage signal held by the FD 142, or a so-called source follower circuit. That is, a source electrode of the amplification transistor AMP 144 is coupled to the vertical signal line Lsig via the selection transistor SEL 135 to thereby configure the source follower circuit with a constant current source coupled to one end of the vertical signal line Lsig.

The selection transistor SEL 145 is coupled between the source electrode of the amplification transistor AMP 144 and the vertical signal line Lsig. A drive signal SELsig is applied to a gate electrode of the selection transistor SEL 145. When the drive signal SELsig is brought into an active state, the selection transistor SEL 145 is brought into an electrically-conductive state, and the unit pixel P is brought into a selected state. This allows a readout signal (pixel signal) outputted from the amplification transistor AMP 144 to be outputted to the vertical signal line Lsig via the selection transistor SEL 145.

### 1-3. Workings and Effects

In the photoelectric conversion element (organic photoelectric conversion section 10) of the present embodiment, the buffer layer 12 including a mellitic derivative represented by the above general formula (1) is provided between the lower electrode 11 and the organic photoelectric conversion layer 13, which is provided between the lower electrode 11 and the upper electrode 14 disposed to be opposed to each other. This improves heat resistance of the buffer layer 12. This is described below.

As described above, it has been reported, in the photoelectric conversion element formed using an organic material, that a charge injection blocking layer including a material with a naphthalene diimide structure, for example, and an underlayer including a material with a pyridine terminal, for example, are stacked in this order between the first electrode and the organic photoelectric conversion layer, for example, from a side of the first electrode, thereby enabling achievement of a reduction in a dark current value as well as a reduction in a temporal change in the dark current value.

However, the above-described method involves the issue of increased manufacturing steps due to the formation of the stacked film of the charge injection blocking layer and the underlayer. Reasons for the formation of the stacked film using the above-described two types of materials between first electrode and the organic photoelectric conversion layer are that the naphthalene diimides are likely to crystallize to cause time degradation to likely to occur and that the heat resistance is low.

In contrast, in the organic photoelectric conversion section 10 of the present embodiment, the buffer layer 12 is formed using the mellitic acid derivative represented by the above general formula (1) between the lower electrode 11 and the organic photoelectric conversion layer 13. This mellitic acid derivative has an equivalent energy level as compared with those of naphthalene diimides, but is less likely to crystallize. This suppresses time degradation in the buffer layer 12 and improves the heat resistance.

As described above, according to the organic photoelectric conversion section 10 of the present embodiment, the formation of the buffer layer 12 using the mellitic acid derivative represented by the above general formula (1) suppresses the time degradation in the buffer layer 12 and improves the heat resistance. Thus, it is possible to improve heat resistance of the imaging element 1 including the buffer layer 12.

In addition, according to the organic photoelectric conversion section 10 of the present embodiment and the imaging element 1 including the organic photoelectric conversion section 10, the formation of the buffer layer 12 using the mellitic acid derivative represented by the above general formula (1) makes it possible to achieve similar effects only by a single layer, as compared with the case of using the naphthalene diimides for the formation. Thus, it is possible to reduce the manufacturing steps.

Next, description is given of Modification Examples 1 to 3, an application example, and practical application examples of the present disclosure. Hereinafter, components similar to those of the above-described embodiment are denoted by the same reference numerals, and descriptions thereof are omitted as appropriate.

### 2. MODIFICATION EXAMPLES

### 2-1. Modification Example 1

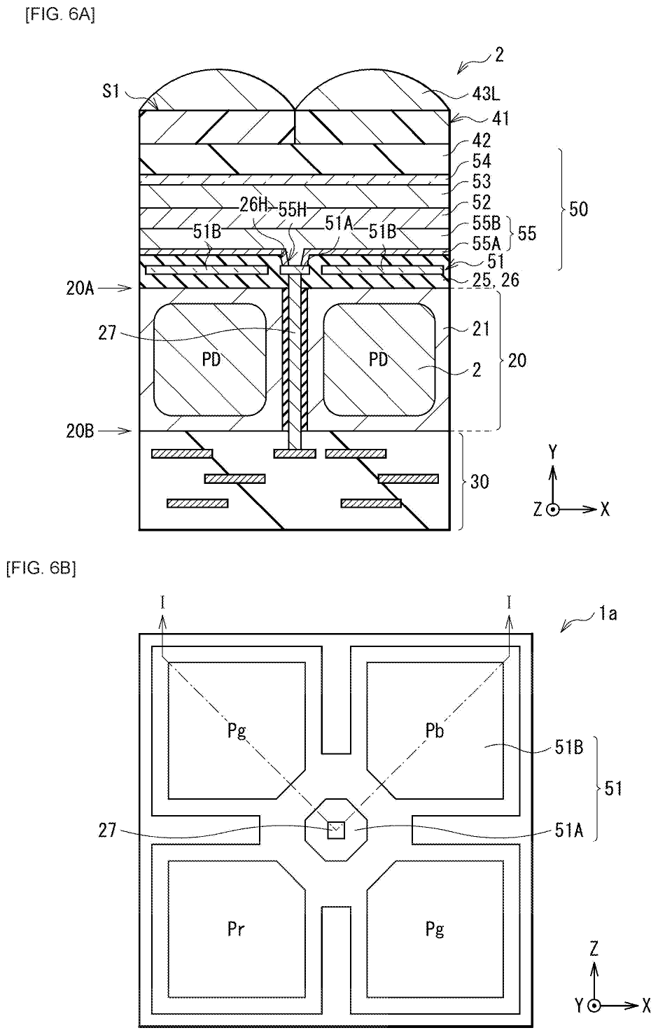

FIG. 6A schematically illustrates a cross-sectional configuration of an imaging element 2 according to Modification Example 1 of the present disclosure. FIG. 6B schematically illustrates an example of a planar configuration of the imaging element 2 illustrated in FIG. 6A, and FIG. 6A illustrates a cross-section along a line I-I illustrated in FIG. 6B. Similarly to the above embodiment, the imaging element 2 is a so-called vertical spectroscopic imaging element in which, for example, one organic photoelectric conversion section 50 and one inorganic photoelectric conversion section 22 are stacked in a vertical direction. In the pixel section 100, as illustrated in FIG. 6B, a pixel unit 1a including four pixels arranged in two rows×two columns is a repeating unit, for example, and the pixel units 1a are repeatedly arranged in array in a row direction and a column direction.

In the imaging element 2 of the present modification example, the color filters 41 that selectively transmits red light (R), green light (G), and blue light (B) are provided for the respective unit pixels P above the organic photoelectric conversion section 50 (light incident side S1). Specifically, in the pixel unit 1a including four pixels arranged in two rows x two columns, two color filters each of which selectively transmits green light (G) are arranged on a diagonal line, and the color filters that selectively transmit red light (R) and blue light (B) are arranged one by one on the orthogonal diagonal line. The unit pixels P (Pr, Pg, and Pb) provided with the respective color filters detect corresponding color light beams, for example, in the photoelectric conversion section 50. That is, the respective unit pixels P (Pr, Pg, and Pb) that detect red light (R), green light (G), and blue light (B) have a Bayer arrangement in the pixel section 100. The inorganic photoelectric conversion section 22 detects light of a wavelength region different from that of the organic photoelectric conversion section 50 (e.g., light in an infrared region (infrared ray (IR)) having a wavelength 700 nm or more and 1000 nm or less).

The organic photoelectric conversion section 50 has a configuration in which, for example, a lower electrode 51, a semiconductor layer 55, a buffer layer 52, an organic photoelectric conversion layer 53, and an upper electrode 54 are stacked in this order, and an insulating layer (e.g., interlayer insulating layer 26) is further provided between the lower electrode 51 and the semiconductor layer 55. The organic photoelectric conversion section 50 corresponds to a specific example of a “photoelectric conversion element” of the present disclosure, and the lower electrode 51, the buffer layer 52, the semiconductor layer 55, and the upper electrode 54 have configurations similar to those of the organic photoelectric conversion section 10 in the foregoing Modification Example 1.

The lower electrode 51 is provided, for example, in the layer of the interlayer insulating layer 26, and includes, as multiple electrodes independent of each other, a readout electrode 51A and an accumulation electrode 51B, for example. The readout electrode 51A and the accumulation electrode 51B are able to apply voltages independently of each other. An opening 26H is formed in the interlayer insulating layer 26 on the readout electrode 51A, and is electrically coupled to the semiconductor layer 55.

The semiconductor layer 55 is provided to accumulate electric charges generated in the organic photoelectric conversion layer 53, and has a stacked structure of a layer 55A and a layer 55B, for example. The layer 55A is provided to prevent electric charges accumulated in the semiconductor layer 55 from being trapped at an interface with an interlayer insulating layer 67 and to efficiently transfer the electric charges to the readout electrode 51A. The layer 55B is provided to prevent electric charges generated in the organic photoelectric conversion layer 53 from being trapped at an interface with the semiconductor layer 55. In the layer 55A, an opening 55H is provided in the opening 26H on the readout electrode 51A to allow for electrical coupling between the readout electrode 51A and the layer 55B. The layers 55A and 55B can be formed using an oxide semiconductor material, for example.

In the imaging element 2, similarly to the foregoing embodiment, light beams (red light (R), green light (G), and blue light (B)) in a visible light region, of the light transmitted through the color filter 41, are absorbed by the organic photoelectric conversion section 50 of the unit pixels (Pr, Pg, and Pb), respectively, provided with the respective color filters, whereas other light beams, e.g., an infrared ray (IR) is transmitted through the organic photoelectric conversion section 50. The infrared ray (IR) transmitted through the organic photoelectric conversion section 50 is detected by the inorganic photoelectric conversion section 22 of each of the unit pixels Pr, Pg, and Pb, and signal charges corresponding to the infrared ray (IR) are generated in each of the unit pixels Pr, Pg, and Pb. That is, it is possible for the imaging element 2 to generate both of a visible light image and an infrared image simultaneously.

### 2-2. Modification Example 2

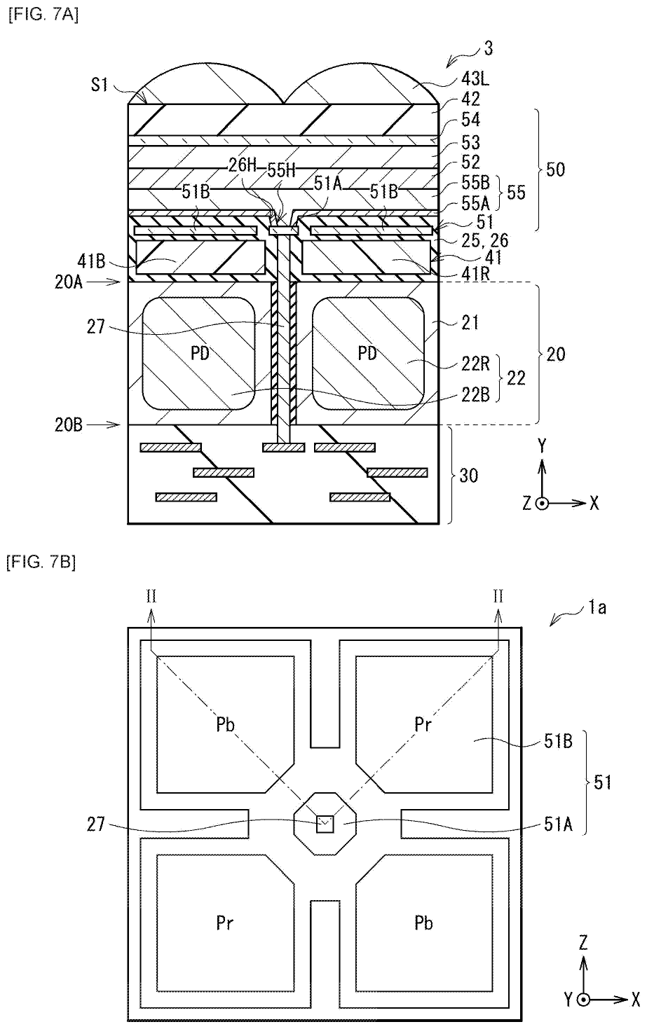

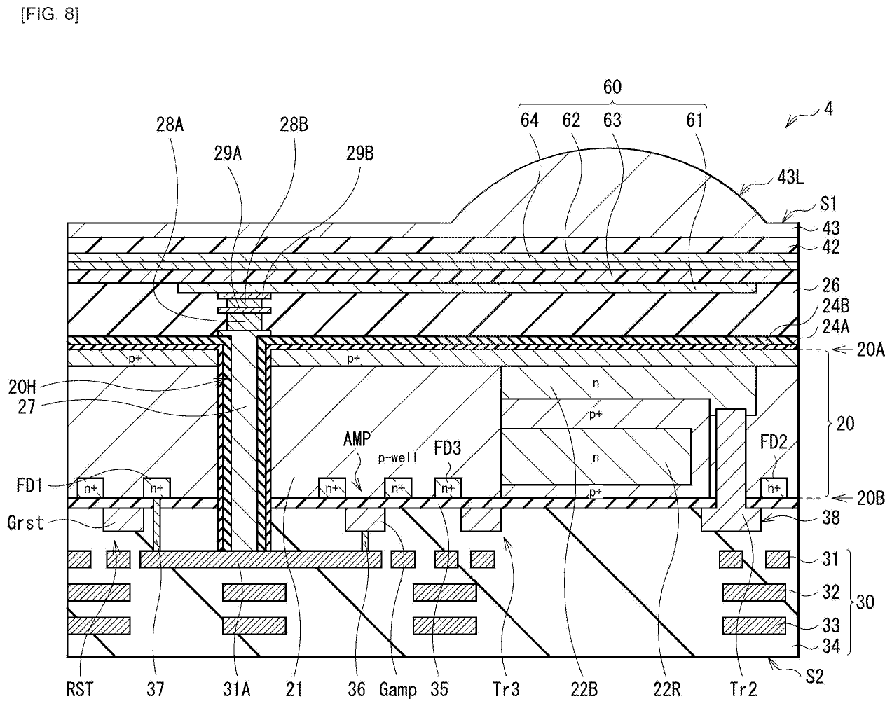

FIG. 7A schematically illustrates a cross-sectional configuration of an imaging element 3 according to Modification Example 2 of the present disclosure. FIG. 7B schematically illustrates an example of a planar configuration of the imaging element 3 illustrated in FIG. 7A, and FIG. 7A illustrates a cross-section along a line II-II illustrated in FIG. 7B. The foregoing Modification Example 1 exemplifies the case where the color filters 41 that selectively transmit red light (R), green light (G) and blue light (B) are provided above the organic photoelectric conversion section 50 (light incident side S1); however, the color filters 41 may be provided between the inorganic photoelectric conversion section 22 and the organic photoelectric conversion section 50, for example, as illustrated in FIG. 7A.

The imaging element 3 has a configuration in which, for example, color filters (color filters 41R) each of which selectively transmits at least red light (R) and color filters (color filters 41B) each of which selectively transmits at least blue light (B) are arranged on the respective diagonal lines in the pixel unit 1a. The organic photoelectric conversion section 50 (organic photoelectric conversion layer 53) is configured to selectively absorb a wavelength corresponding to green light, for example. This allows the organic photoelectric conversion section 50 and the respective inorganic photoelectric conversion sections 22 (inorganic photoelectric conversion sections 22R and 22G) arranged below the color filters 41R and 41B to acquire signals corresponding to blue light (B) or red light (R). The imaging element 3 according to the present modification example enables the respective photoelectric conversion sections of R, G, and B to each have a larger area than that of a photoelectric conversion element having a typical Bayer arrangement. This makes it possible to improve the S/N ratio.

### 2-3. Modification Example 3

FIG. 8 schematically illustrates an example of a cross-sectional configuration of an imaging element 4 according to Modification Example 3 of the present disclosure. The imaging element 4 is used for a CMOS image sensor to be used, for example, in an electronic apparatus such as a digital still camera or a video camera. The foregoing embodiment exemplifies the use of electrons as signal charges, but this is not limitative; holes may be used as signal charges. In the imaging element 4 of the present modification example, for example, holes, of the electron-hole pairs generated by photoelectric conversion, are read as signal charges from a side of a lower electrode 61.

In the imaging element 4 of the present modification example, one organic photoelectric conversion section 60 and two inorganic photoelectric conversion sections 22B and 22R are stacked in a vertical direction for each unit pixel P. The organic photoelectric conversion section 60 is provided on a side of a back surface (first surface 20A) of the semiconductor substrate 20. The inorganic photoelectric conversion sections 22B and 22R are each formed to be embedded inside the semiconductor substrate 20, and are stacked in a thickness direction of the semiconductor substrate 20.

The organic photoelectric conversion section 60 and the inorganic photoelectric conversion sections 22B and 22R selectively detect light beams of different wavelength bands and perform photoelectric conversion. For example, the organic photoelectric conversion section 60 acquires a color signal of green (G). The inorganic photoelectric conversion sections 22B and 22R acquire color signals of blue (B) and red (R), respectively, depending on differences in absorption coefficients. This enables the imaging element 4 to acquire multiple types of color signals in one pixel (unit pixel P) without using a color filter.

In the present modification example, description is given of a case of reading holes, of the electron-hole pairs generated by photoelectric conversion, as signal charges (a case of adopting a p-type semiconductor region as a photoelectric conversion layer) as described above. In addition, in the diagram, “+ (plus)” attached to “p” and “n” indicates that p-type or n-type impurity concentration is high.

The semiconductor substrate 20 is configured by, for example, an n-type silicon (Si) substrate, and includes the p-well 21 in a predetermined region. The second surface (a front surface of the semiconductor substrate 20) 20B of the p-well 21 is provided with, for example, various floating diffusions (floating diffusion layers) FD (e.g., FD1, FD2, and FD3), various transistors Tr (e.g., a vertical transistor (transfer transistor) Tr2, a transfer transistor Tr3, the amplification transistor (modulation element) AMP, and the reset transistor RST), and the multilayer wiring layer 30. The multilayer wiring layer 30 has a configuration in which, for example, the wiring layers 31, 32, and 33 are stacked inside the insulating layer 34. In addition, a peripheral part of the semiconductor substrate 20 is provided with a peripheral circuit (unillustrated) including a logic circuit or the like.

In the organic photoelectric conversion section 60, the lower electrode 61, an organic photoelectric conversion layer 63, a buffer layer 62, and an upper electrode 64 are stacked in this order. The organic photoelectric conversion section 60 has a configuration similar to that of the organic photoelectric conversion section 10 in the foregoing embodiment except the stacking order of the organic photoelectric conversion layer 63 and the buffer layer 62. The buffer layer 62 functions as a so-called electron transport/hole blocking layer that selectively transfers electrons, of the electric charges generated in the organic photoelectric conversion layer 63, to the upper electrode 64 and inhibits movement of holes to a side of the upper electrode 64.

The inorganic photoelectric conversion sections 22B and 22R are configured by, for example, a PIN (Positive Intrinsic Negative) type photodiode, and each thereof has a p-n junction in a predetermined region of the semiconductor substrate 20. The inorganic photoelectric conversion sections 22B and 22R of the present modification example enable spectroscopy on light in the vertical direction by utilizing a difference in wavelength bands to be absorbed depending on incidence depth of light in the silicon substrate.

The inorganic photoelectric conversion section 22B selectively detects blue light and accumulates signal charges corresponding to a blue color; the inorganic photoelectric conversion section 22B is provided at a depth at which the blue light is able to be efficiently subjected to photoelectric conversion. The inorganic photoelectric conversion section 22R selectively detects red light and accumulates signal charges corresponding to a red color; the inorganic photoelectric conversion section 22R is provided at a depth at which the red light is able to be efficiently subjected to photoelectric conversion. It is to be noted that blue (B) is a color corresponding to a wavelength band of 450 nm or more and less than 495 nm, for example, and red (R) is a color corresponding to a wavelength band of 620 nm or more and less than 750 nm, for example. It is sufficient for each of the inorganic photoelectric conversion sections 22B and 22R to be able to detect light of a portion or all of the respective wavelength bands.

Specifically, as illustrated in FIG. 8, each of the inorganic photoelectric conversion section 22B and the inorganic photoelectric conversion section 22R includes, for example, a p+ region serving as a hole accumulation layer and an n region serving as an electron accumulation layer (having a p-n-p stacked structure). The n region of the inorganic photoelectric conversion section 22B is coupled to the vertical transistor Tr2. The p+ region of the inorganic photoelectric conversion section 22B bends along the vertical transistor Tr2, and is linked to the p+ region of the inorganic photoelectric conversion section 22R.

The vertical transistor Tr2 is a transfer transistor that transfers, to the floating diffusion FD2, the signal charges corresponding to the blue color generated and accumulated in the inorganic photoelectric conversion section 22B. The inorganic photoelectric conversion section 22B is formed at a deep position from the second surface 20B of the semiconductor substrate 20, and thus the transfer transistor of the inorganic photoelectric conversion section 22B is preferably configured by the vertical transistor Tr2.

The transfer transistor Tr3 transfers, to the floating diffusion FD3, the signal charges corresponding to the red color generated and accumulated in the inorganic photoelectric conversion section 22R, and is configured by, for example, a MOS transistor.

The amplification transistor AMP is, for example, a modulation element that modulates an amount of electric charges generated in the organic photoelectric conversion section 60, and is configured by, for example, a MOS transistor.

The reset transistor RST resets electric charges transferred, for example, from the organic photoelectric conversion section 60 to the floating diffusion FD1, and is configured by, for example, a MOS transistor.

A fixed charge layer 24A and an insulating layer 24B are stacked in this order, for example, from a side of the semiconductor substrate 20 between the first surface 20A of the semiconductor substrate 20 and the lower electrode 61. A protective layer 42 is provided on the upper electrode 64. An on-chip lens layer 43, which configures an on-chip lens 43L and serves also as a planarization layer, is disposed above the protective layer 42.

The through-electrode 27 is provided between the first surface 20A and the second surface 20B of the semiconductor substrate 20. The organic photoelectric conversion section 60 is coupled to a gate Gamp of the amplification transistor AMP and the floating diffusion FD1 via the through-electrode 27. This makes it possible for the imaging element 4 to favorably transfer electric charges (e.g., holes) generated in the organic photoelectric conversion section 60 on a side of the first surface 20A of the semiconductor substrate 20 to a side of the second surface 20B of the semiconductor substrate 20 via the through-electrode 27, and thus to enhance the characteristics.

The through-electrode 27 is provided for each unit pixel P, for example. The through-electrode 27 functions as a connector between the organic photoelectric conversion section 60 and the gate Gamp of the amplification transistor AMP as well as the floating diffusion FD1, and serves as a transmission path for electric charges generated in the organic photoelectric conversion section 60.

The upper end of the through-electrode 27 is coupled to the lower electrode 61 via an upper first contact 28A, a pad section 29A, an upper second contact 28B, and a pad section 29B provided in the interlayer insulating layer 26, for example. The lower end of the through-electrode 27 is coupled to, for example, a coupling section 31A inside the wiring layer 31, and the coupling section 31A and the gate Gamp of the amplification transistor AMP are coupled to each other via a lower first contact 36. The coupling section 31A and the floating diffusion FD1 are coupled to the lower electrode 61 via a lower second contact 37. It is to be noted that, FIG. 8 illustrates the through-electrode 27 as having a cylindrical shape, but this is not limitative; the through-electrode 27 may also have a tapered shape, for example.

As illustrated in FIG. 8, a reset gate Grst of the reset transistor RST is preferably disposed next to the floating diffusion FD1. This makes it possible to reset electric charges accumulated in the floating diffusion FD1 by the reset transistor RST.

The upper first contact 28A, the pad section 29A, the upper second contact 28B, the pad section 29B, the lower first contact 36, and the lower second contact 37 are each configured by a doped silicon material such as PDAS (Phosphorus Doped Amorphous Silicon), or a metal material such as aluminum (Al), tungsten (W), titanium (Ti), cobalt (Co), hafnium (Hf), or tantalum (Ta), for example.

The protective layer 42 is configured by a light-transmissive material, and is configured by, for example, a monolayer film of one of silicon oxide (SiOₓ), silicon nitride (SiNₓ), silicon oxynitride (SiOₓN_{y}), or the like, or alternatively is configured by a stacked film of two or more thereof.

The on-chip lens layer 43 is formed on the protective layer 42 to cover the entire surface thereof. Multiple on-chip lenses (microlenses) 43L are provided on a front surface of the on-chip lens layer 43. The on-chip lens 43L condenses light incident from above on respective light-receiving surfaces of the organic photoelectric conversion section 60 and the inorganic photoelectric conversion sections 22B and 22R. In the present modification example, the multilayer wiring layer 30 is formed on the side of the second surface 20B of the semiconductor substrate 20. This enables the respective light-receiving surfaces of the organic photoelectric conversion section 60 and the inorganic photoelectric conversion sections 22B and 22R to be arranged close to each other, thus making it possible to reduce variations in sensitivities between colors generated depending on a F-value of the on-chip lens 43L.

As described above, in the imaging element 4 of the present modification example, the buffer layer 62 including the mellitic acid derivative represented by the above general formula (1) is provided between the organic photoelectric conversion layer 63 and the upper electrode 64. This suppresses time degradation in the buffer layer 62 and improves the heat resistance, similarly to the foregoing embodiment. Thus, it is possible to improve heat resistance of the imaging element 4 including the buffer layer 62.

In addition, according to the organic photoelectric conversion section 60 of the present modification example and the imaging element 4 including the organic photoelectric conversion section 60, the formation of the buffer layer 62 using the mellitic acid derivative represented by the above general formula (1) makes it possible to achieve similar effects using a single layer, as compared with the case of using the naphthalene diimides for the formation. Thus, it is possible to reduce the manufacturing steps.

### 3. APPLICATION EXAMPLE

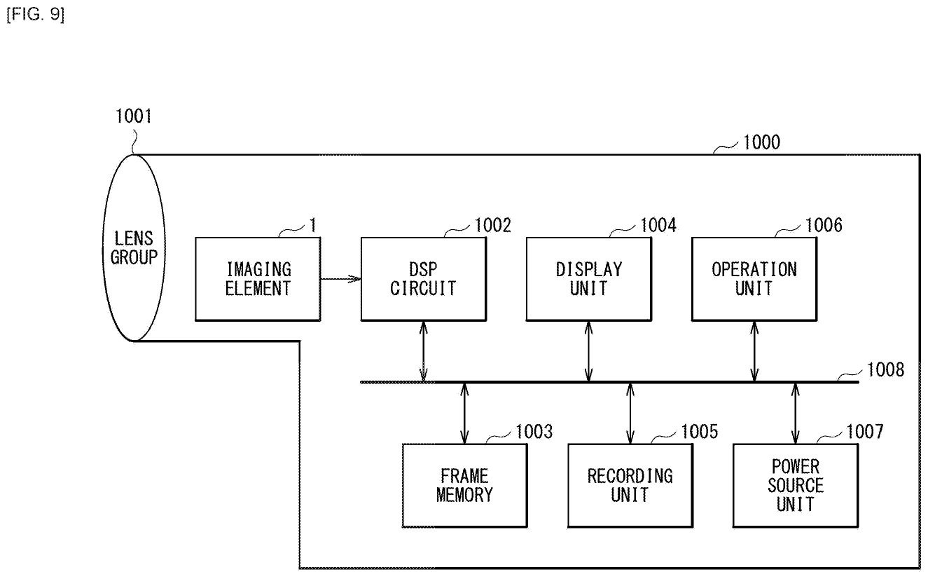

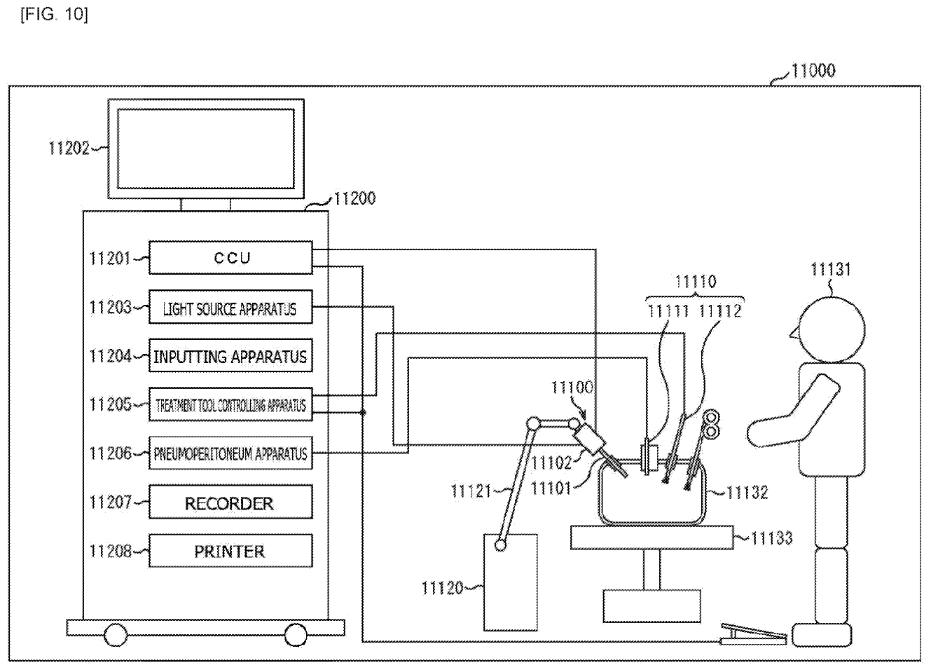

The above-described imaging element 1 or the like is applicable, for example, to any type of electronic apparatus with an imaging function including a camera system such as a digital still camera and a video camera, a mobile phone having an imaging function, and the like. FIG. 9 illustrates an outline configuration of an electronic apparatus 1000.

The electronic apparatus 1000 includes, for example, a lens group 1001, the imaging element 1, a DSP (Digital Signal Processor) circuit 1002, a frame memory 1003, a display unit 1004, a recording unit 1005, an operation unit 1006, and a power source unit 1007. They are coupled to each other via a bus line 1008.

The lens group 1001 takes in incident light (image light) from a subject, and forms an image on an imaging surface of the imaging element 1. The imaging element 1 converts the amount of incident light formed as an image on the imaging surface by the lens group 1001 into electric signals on a pixel-by-pixel basis, and supplies the DSP circuit 1002 with the electric signals as pixel signals.

The DSP circuit 1002 is a signal processing circuit that processes signals supplied from the imaging element 1. The DSP circuit 1002 outputs image data obtained by processing the signals from the imaging element 1. The frame memory 1003 temporarily holds the image data processed by the DSP circuit 1002 in units of frames.

The display unit 1004 includes, for example, a panel-type display device such as a liquid crystal panel or an organic EL (Electro Luminescence) panel, and records image data of a moving image or a still image captured by the imaging element 1 in a recording medium such as a semiconductor memory or a hard disk.

The operation unit 1006 outputs an operation signal for a variety of functions of the electronic apparatus 1000 in accordance with an operation by a user. The power source unit 1007 appropriately supplies the DSP circuit 1002, the frame memory 1003, the display unit 1004, the recording unit 1005, and the operation unit 1006 with various kinds of power for operations of these supply targets.

### 4. PRACTICAL APPLICATION EXAMPLES

### Example of Practical Application to Endoscopic Surgery System

The technology according to an embodiment of the present disclosure (present technology) is applicable to various products. For example, the technology according to an embodiment of the present disclosure may be applied to an endoscopic surgery system.

FIG. 10 is a view depicting an example of a schematic configuration of an endoscopic surgery system to which the technology according to an embodiment of the present disclosure (present technology) can be applied.

In FIG. 10, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

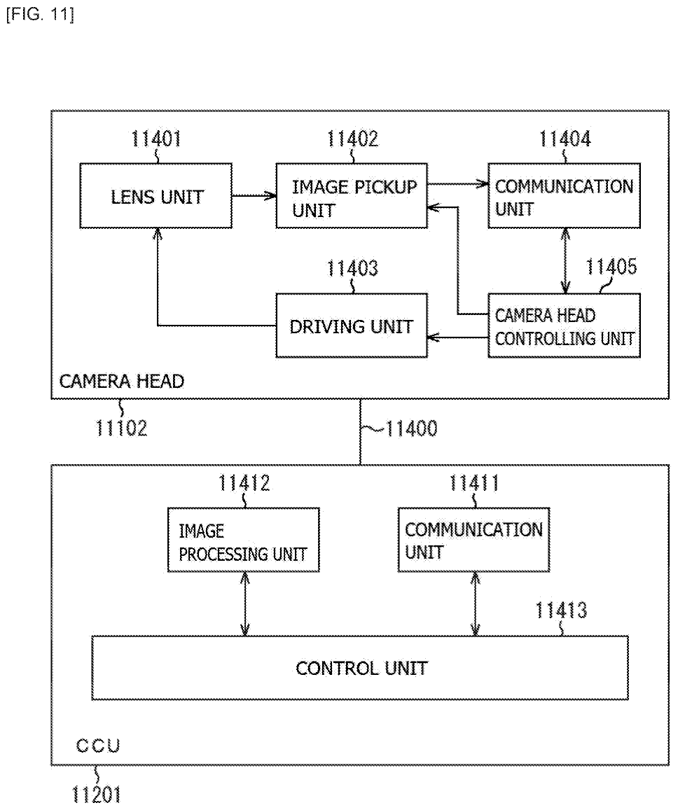

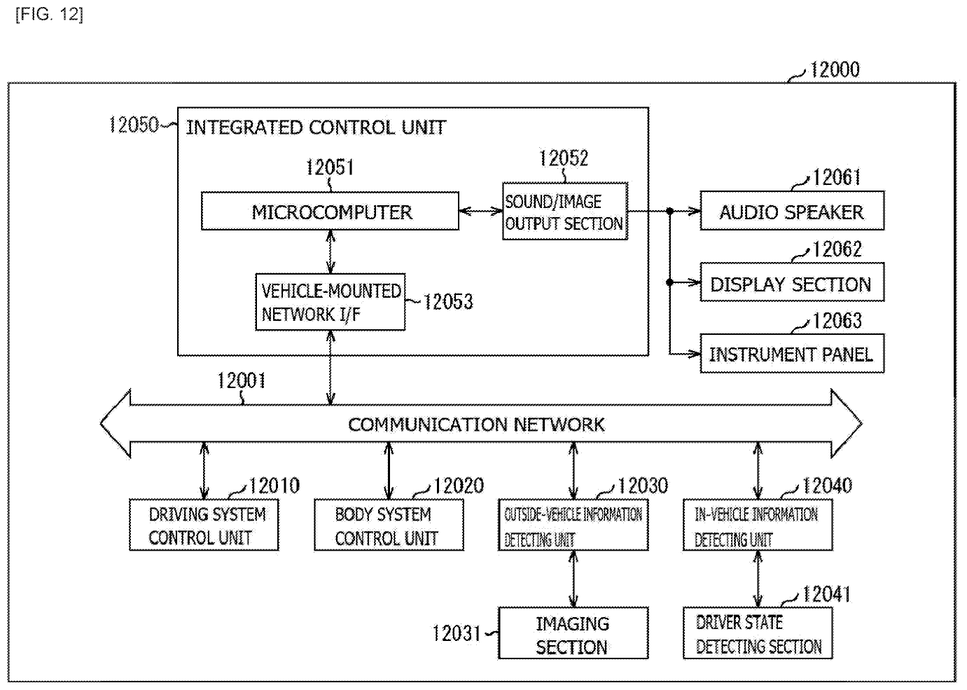

FIG. 11 is a block diagram depicting an example of a functional configuration of the camera head 11102 and the CCU 11201 depicted in FIG. 10.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to an embodiment of the present disclosure is applicable. The technology according to an embodiment of the present disclosure is applicable to, for example, the image pickup unit 11402 of the configurations described above. Applying the technology according to an embodiment of the present disclosure to the image pickup unit 11402 makes it possible to improve heat resistance.

It is to be noted that although the endoscopic surgery system has been described as an example here, the technology according to an embodiment of the present disclosure may also be applied to, for example, a microscopic surgery system, and the like.

### Example of Practical Application to Mobile Body

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, a robot, a construction machine, and an agricultural machine (tractor).

FIG. 12 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 12, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 12, an audio speaker 12061, a display section 12062, and an instrument panel 12063 are illustrated as the output device. The display section 12062 may, for example, include at least one of an on-board display and a head-up display.

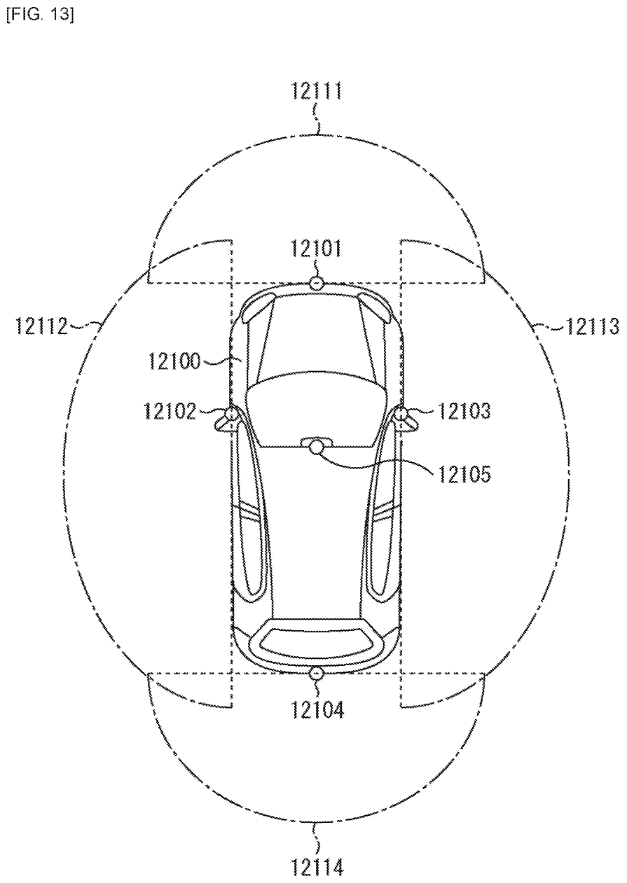

FIG. 13 is a diagram depicting an example of the installation position of the imaging section 12031.

In FIG. 13, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 13 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Description has been given hereinabove referring to the embodiment, Modification Examples 1 to 3, Application Example, and Practical Application Examples; however, the content of the present disclosure is not limited to the foregoing embodiment and the like, and may be modified in a wide variety of ways. For example, the numbers and ratios of the organic photoelectric conversion section and the inorganic photoelectric conversion section are not limited.

In addition, the foregoing embodiment and the like exemplify the configuration of the back-illuminated solid-state imaging device; however, the content of the present disclosure is also applicable to a front-illuminated solid-state imaging device. Further, the photoelectric conversion element of the present disclosure need not include all of the components described in the foregoing embodiment, and may include any other layer, conversely.

It is to be noted that the effects described herein are merely exemplary and are not limitative, and may further include other effects.

It is to be noted that the present disclosure may also have the following configurations. According to the present technology of the following configurations, providing a buffer layer including a mellitic acid derivative represented by the above general formula (1) that is less likely to crystallize than naphthalene diimides, for example, between the first electrode and the organic photoelectric conversion layer, which is provided between the first electrode and the second electrode disposed to be opposed to each other, allows for an improvement in the heat resistance of the buffer layer. This makes it possible to improve the heat resistance of the imaging device including the buffer layer.

[1]

A photoelectric conversion element including:
a first electrode;
a second electrode disposed to be opposed to the first electrode;
an organic photoelectric conversion layer provided between the first electrode and second electrode; and
a buffer layer provided between the first electrode and the organic photoelectric conversion layer, the buffer layer including a mellitic acid derivative represented by the following general formula (1).

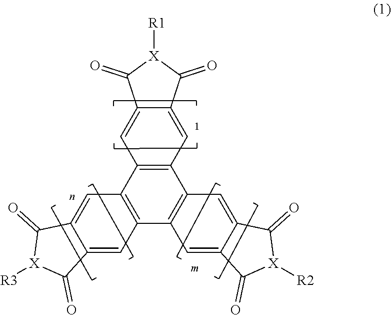

(X is each independently an oxygen atom, a nitrogen atom, or a sulfur atom. R1 to R3 are each independently a hydrogen atom, a halogen atom, an aromatic hydrocarbon group having 6 to 60 carbon atoms, an aromatic heterocyclic group having 3 to 30 carbon atoms, a haloalkyl group having 1 to 30 carbon atoms, an alkylamino group having 1 to 30 carbon atoms, a dialkylamino group having 2 to 60 carbon atoms, an alkylsulfonyl group having 1 to 30 carbon atoms, a haloalkylsulfonyl group having 1 to 3 carbon atoms, an alkylsilyl group having 3 to 30 carbon atoms, an alkylsilylacetylene group having 5 to 60 carbon atoms, a cyano group, or a derivative thereof. l, m, and n are an integer of 0 or 1 or more and 5 or less.)

[2]

The photoelectric conversion element according to [1], in which R1 to R3 of the mellitic acid derivative represented by the general formula (1) are a 4-pyridyl group.

[3]

The photoelectric conversion element according to [1] or [2], in which the mellitic acid derivative represented by the general formula (1) has a Lowest Unoccupied Molecular Orbital (LUMO) level same as or deeper than electron affinity of the organic photoelectric conversion layer.

[4]

The photoelectric conversion element according to any one of [1] to [3], in which the LUMO level of the mellitic acid derivative represented by the general formula (1) has a value deeper than 4.0 eV.

[5]

The photoelectric conversion element according to any one of [1] to [4], in which the organic photoelectric conversion layer includes a first organic semiconductor material and a second organic semiconductor material.

[6]

The photoelectric conversion element according to [5], in which the first organic semiconductor material includes an electron-transporting material.

[7]

The photoelectric conversion element according to [5] or [6], in which the first organic semiconductor material includes fullerene or a fullerene derivative.

[8]

The photoelectric conversion element according to any one of [5] to [7], in which the second organic semiconductor material includes a hole-transporting material.

[9]

The photoelectric conversion element according to any one of [5] to [8], in which the organic photoelectric conversion layer further includes a dye material having a predetermined absorption waveform in a visible light region.

[10]

An imaging device including multiple pixels each provided with one or multiple photoelectric conversion elements,
the photoelectric conversion element including
   a first electrode,
   a second electrode disposed to be opposed to the first electrode,
   an organic photoelectric conversion layer provided between the first electrode and second electrode, and
   a buffer layer provided between the first electrode and the organic photoelectric conversion layer, the buffer layer including a mellitic acid derivative represented by the following general formula (1).

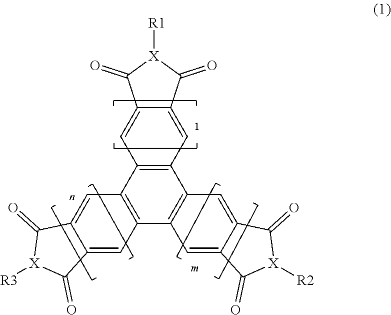

(X is each independently an oxygen atom, a nitrogen atom, or a sulfur atom. R1 to R3 are each independently a hydrogen atom, a halogen atom, an aromatic hydrocarbon group having 6 to 60 carbon atoms, an aromatic heterocyclic group having 3 to 30 carbon atoms, a haloalkyl group having 1 to 30 carbon atoms, an alkylamino group having 1 to 30 carbon atoms, a dialkylamino group having 2 to 60 carbon atoms, an alkylsulfonyl group having 1 to 30 carbon atoms, a haloalkylsulfonyl group having 1 to 3 carbon atoms, an alkylsilyl group having 3 to 30 carbon atoms, an alkylsilylacetylene group having 5 to 60 carbon atoms, a cyano group, or a derivative thereof. l, m, and n are an integer of 0 or 1 or more and 5 or less.)

[11]

The imaging device according to [10], in which, in each of the pixels, one or multiple organic photoelectric conversion sections and one or multiple inorganic photoelectric conversion sections are stacked, the one or the multiple organic photoelectric conversion sections having a configuration of the photoelectric conversion element, the one or the multiple inorganic photoelectric conversion sections performing photoelectric conversion of a wavelength region different from the organic photoelectric conversion section.

[12]

The imaging device according to [11], in which
the inorganic photoelectric conversion section is formed to be embedded inside a semiconductor substrate, and
the organic photoelectric conversion section is formed on a side of a first surface of the semiconductor substrate.
   [13]

The imaging device according to [12], in which a multilayer wiring layer is formed on a side of a second surface of the semiconductor substrate.

[14]

The imaging device according to any one of [11] to [13]], in which
the organic photoelectric conversion section performs photoelectric conversion of light in a visible light region, and
the inorganic photoelectric conversion section performs photoelectric conversion of light in an infrared region.
   [15]

The imaging device according to [12] or [13], in which
the organic photoelectric conversion section performs photoelectric conversion of green light, and
the inorganic photoelectric conversion section that performs photoelectric conversion of blue light and the inorganic photoelectric conversion section that performs photoelectric conversion of red light are arranged side by side inside the semiconductor substrate.
   [16]

The imaging device according to [12] or [13], in which
the organic photoelectric conversion section performs photoelectric conversion of green light, and
the inorganic photoelectric conversion section that performs photoelectric conversion of blue light and the inorganic photoelectric conversion section that performs photoelectric conversion of red light are stacked inside the semiconductor substrate.

This application claims the benefit of Japanese Priority Patent Application JP2020-156660 filed with the Japan Patent Office on Sep. 17, 2020, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A photoelectric conversion element comprising:
a first electrode;
a second electrode disposed to be opposed to the first electrode;
an organic photoelectric conversion layer provided between the first electrode and second electrode; and
a buffer layer provided between the first electrode and the organic photoelectric conversion layer, the buffer layer including a mellitic acid derivative represented by the following general formula (1). 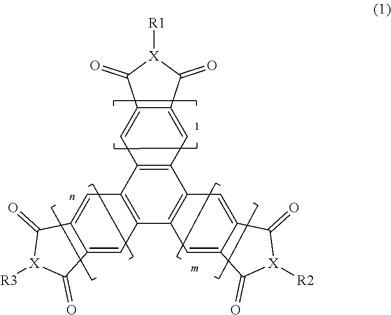
(X is each independently an oxygen atom, a nitrogen atom, or a sulfur atom. R1 to R3 are each independently a hydrogen atom, a halogen atom, an aromatic hydrocarbon group having 6 to 60 carbon atoms, an aromatic heterocyclic group having 3 to 30 carbon atoms, a haloalkyl group having 1 to 30 carbon atoms, an alkylamino group having 1 to 30 carbon atoms, a dialkylamino group having 2 to 60 carbon atoms, an alkylsulfonyl group having 1 to 30 carbon atoms, a haloalkylsulfonyl group having 1 to 3 carbon atoms, an alkylsilyl group having 3 to 30 carbon atoms, an alkylsilylacetylene group having 5 to 60 carbon atoms, a cyano group, or a derivative thereof. l, m, and n are an integer of 0 or 1 or more and 5 or less.)

2. The photoelectric conversion element according to claim 1, wherein R1 to R3 of the mellitic acid derivative represented by the general formula (1) are a 4-pyridyl group.

3. The photoelectric conversion element according to claim 1, wherein the mellitic acid derivative represented by the general formula (1) has a Lowest Unoccupied Molecular Orbital (LUMO) level same as or deeper than electron affinity of the organic photoelectric conversion layer.

4. The photoelectric conversion element according to claim 1, wherein a LUMO level of the mellitic acid derivative represented by the general formula (1) has a value deeper than 4.0 eV.

5. The photoelectric conversion element according to claim 1, wherein the organic photoelectric conversion layer includes a first organic semiconductor material and a second organic semiconductor material.

6. The photoelectric conversion element according to claim 5, wherein the first organic semiconductor material comprises an electron-transporting material.

7. The photoelectric conversion element according to claim 5, wherein the first organic semiconductor material comprises fullerene or a fullerene derivative.

8. The photoelectric conversion element according to claim 5, wherein the second organic semiconductor material comprises a hole-transporting material.

9. The photoelectric conversion element according to claim 5, wherein the organic photoelectric conversion layer further includes a dye material having a predetermined absorption waveform in a visible light region.

10. An imaging device comprising multiple pixels each provided with one or multiple photoelectric conversion elements,
the photoelectric conversion element including
a first electrode,
a second electrode disposed to be opposed to the first electrode,
an organic photoelectric conversion layer provided between the first electrode and second electrode, and
a buffer layer provided between the first electrode and the organic photoelectric conversion layer, the buffer layer including a mellitic acid derivative represented by the following general formula (1). 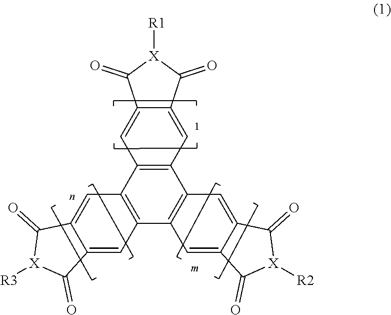
(X is each independently an oxygen atom, a nitrogen atom, or a sulfur atom. R1 to R3 are each independently a hydrogen atom, a halogen atom, an aromatic hydrocarbon group having 6 to 60 carbon atoms, an aromatic heterocyclic group having 3 to 30 carbon atoms, a haloalkyl group having 1 to 30 carbon atoms, an alkylamino group having 1 to 30 carbon atoms, a dialkylamino group having 2 to 60 carbon atoms, an alkylsulfonyl group having 1 to 30 carbon atoms, a haloalkylsulfonyl group having 1 to 3 carbon atoms, an alkylsilyl group having 3 to 30 carbon atoms, an alkylsilylacetylene group having 5 to 60 carbon atoms, a cyano group, or a derivative thereof. l, m, and n are an integer of 0 or 1 or more and 5 or less.)

11. The imaging device according to claim 10, wherein, in each of the pixels, one or multiple organic photoelectric conversion sections and one or multiple inorganic photoelectric conversion sections are stacked, the one or the multiple organic photoelectric conversion sections having a configuration of the photoelectric conversion element, the one or the multiple inorganic photoelectric conversion sections performing photoelectric conversion of a wavelength region different from the organic photoelectric conversion section.

12. The imaging device according to claim 11, wherein
the inorganic photoelectric conversion section is formed to be embedded inside a semiconductor substrate, and
the organic photoelectric conversion section is formed on a side of a first surface of the semiconductor substrate.

13. The imaging device according to claim 12, wherein a multilayer wiring layer is formed on a side of a second surface of the semiconductor substrate.

14. The imaging device according to claim 11, wherein
the organic photoelectric conversion section performs photoelectric conversion of light in a visible light region, and
the inorganic photoelectric conversion section performs photoelectric conversion of light in an infrared region.

15. The imaging device according to claim 12, wherein
the organic photoelectric conversion section performs photoelectric conversion of green light, and
the inorganic photoelectric conversion section that performs photoelectric conversion of blue light and the inorganic photoelectric conversion section that performs photoelectric conversion of red light are arranged side by side inside the semiconductor substrate.

16. The imaging device according to claim 12, wherein
the organic photoelectric conversion section performs photoelectric conversion of green light, and
the inorganic photoelectric conversion section that performs photoelectric conversion of blue light and the inorganic photoelectric conversion section that performs photoelectric conversion of red light are stacked inside the semiconductor substrate.
